(19) United States
(12) Patent Application Publication
(10) Pub. No.: US 2025/0240871 A1
(43) Pub. Date: Jul. 24, 2025

(54) DEVICE WITH LAMINATED STRUCTURE AND METHOD OF MANUFACTURING A LAMINATED STRUCTURE COMPRISING DIELECTRIC LAYERS

(71) Applicant: STMicroelectronics International N.V., Geneva (CH)

(72) Inventors: Deborah COGONI, Notre Dame de l'Osier (FR); Claire LAPORTE, Grenoble (FR); David AUCHERE, Meylan (FR); Laurent SCHWARTZ, La Buisse (FR)

(73) Assignee: STMicroelectronics International N.V., Geneva (CH)

(21) Appl. No.: 19/022,540

(22) Filed: Jan. 15, 2025

(30) Foreign Application Priority Data
Jan. 18, 2024 (FR) FR2400510

(51) Int. Cl. H05K 1/02; H05K 3/00

(52) U.S. Cl. CPC H05K 1/0216; H05K 3/0029; H05K 3/0076; H05K 2201/0187; H05K 2201/10098; H05K 2203/06; H05K 2203/0776; H05K 2203/107

(57) ABSTRACT

A laminated structure includes metal tracks. In a method for making, a first layer of a first dielectric material is deposited on a substrate. One or more openings are then made in the first layer. A second dielectric material is then deposited within the openings formed in the first layer. The second dielectric material has dielectric properties distinct from the dielectric properties of the first dielectric material.

### PRIORITY CLAIM

This application claims the priority benefit of French Application for U.S. Pat. No. 2,400,510, filed on Jan. 18, 2024, the content of which is hereby incorporated by reference in its entirety to the maximum extent allowable by law.

### TECHNICAL FIELD

The present disclosure generally concerns electronic devices with a laminated structure and their manufacturing methods.

### BACKGROUND

An electric current flowing through a conductive structure generates an electromagnetic field in the environment close to this structure. The trajectory of the field lines depends on the properties of the electric current, as well as on the properties of the crossed structures.

Circuits can be manufactured based on substrates formed of a stack of dielectric and conductive layers. The electromagnetic fields generated by the propagation of an electric current in the conductive layers propagate in the neighboring dielectric layers.

When electromagnetic fields overlap, the waves may interfere with one another. A problem may exist in the case of uncontrolled electromagnetic fields which may, for example, cause crosstalk and/or a decrease in the performance of an electronic device.

### SUMMARY

An embodiment provides a method of manufacturing a laminated structure comprising one or a plurality of metal tracks, the method comprising: depositing on a substrate a first layer of a first dielectric material; forming one or a plurality of openings in the first layer; and depositing a second dielectric material, with dielectric properties distinct from the dielectric properties of the first dielectric material, at the location of the openings formed in the first layer.

According to an embodiment, the first dielectric material is deposited by lamination.

According to an embodiment, the openings are formed by laser direct imaging.

According to an embodiment, a mask is deposited on the surface of the first dielectric material after the forming of one or a plurality of openings.

According to an embodiment, the second dielectric material is deposited in liquid form.

Another embodiment provides an electronic device with a laminated structure comprising: one or a plurality of metal tracks; a substrate; a first layer of a first dielectric material; and a second layer of a second dielectric material having dielectric properties distinct from the first material, the second layer being present in openings of the first layer and being in contact with the first layer, the first and the second layer being present in the same level of the device.

According to an embodiment, the first dielectric material is a film of Ajinomoto buildup film (ABF) type.

According to an embodiment, the second dielectric material has a higher dielectric permittivity than the first dielectric material.

According to an embodiment, the second dielectric material has a lower dielectric permittivity than the first dielectric material.

According to an embodiment, the dielectric constant of the second dielectric material is in the range from 3 to 5.

According to an embodiment, the first and the second layers are present in a first level of the device, the device further comprising a second level comprising a third layer of a third dielectric material, the third layer being in contact with one of the first layer or the second layer.

Another embodiment provides an antenna, comprising the above-described device wherein: a first metal track is in a first level and a second metal track is in a second level; and the first layer of the first dielectric material and the second layer of the second dielectric material are formed in a third level so that the second layer covers the second metal track and that the dielectric constant of the second dielectric material is lower than the dielectric constant of the first dielectric material; and further comprising a third layer of a third dielectric material formed in a fourth level so that the fourth level is between the first level and the second level.

According to an embodiment, the dielectric constant of the third dielectric material is higher than the dielectric constant of the second dielectric material.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A illustrates simplified cross-section views of successive steps A to D of a method of manufacturing a laminated electronic device according to a first embodiment;

FIG. 1B illustrates simplified cross-section views of successive steps A′ to G′ of a method of manufacturing a laminated electronic device according to a second embodiment;

FIG. 2 schematically shows a cross-section view of an example of an electronic device with a laminated structure;

FIG. 3A shows a cross-section view of an example of an electronic device;

FIG. 3B shows a cross-section view of the example of the electronic device of FIG. 3A, comprising an additional layer of dielectric material; and

FIG. 4 schematically shows a three-dimensional view of an example of a patch antenna.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

In the following description, by “layer” there is meant a volume of a given material, and by “level” there is meant all the layers present on a same plane of a laminated substrate. There is here called “metallization level” a level comprising conductive tracks, for example metallic.

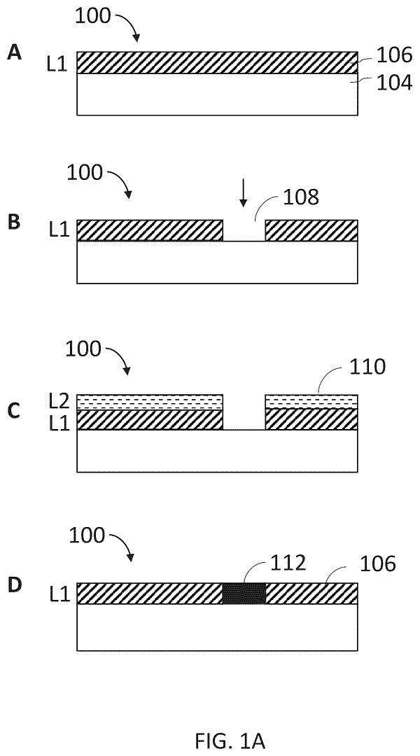

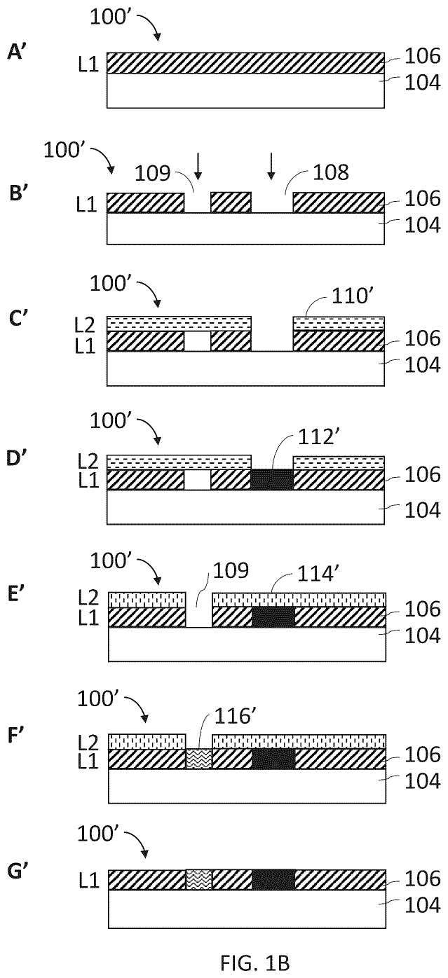

FIG. 1A illustrates simplified cross-section views of successive steps A to D of a method of manufacturing a laminated electronic device 100 according to a first embodiment.

According to an embodiment, device 100 initially comprises a substrate 104. Substrate 104 comprises one or a plurality of levels and comprises, for example, a stack of metallization levels and of dielectric levels (not shown in FIG. 1A).

Substrate 104 is, for example, obtained according to usual methods of manufacturing laminated substrates and/or printed circuit boards (PCB), during which conductive tracks 104 are embedded in a dielectric layer, for example, made of epoxy resin.

A layer 106 of a first dielectric material is deposited (step A) to form a level L1 on the substrate 104 of device 100. The first dielectric material is, for example, an Ajinomoto buildup film (ABF) made of silicon oxide, of alumina, of tantalum oxide, or of titanium oxide. A film of ABF buildup type is a resin composition of an insulating material having a formulation combining organic epoxy resins, a hardener, and an inorganic microparticulate filler.

Dielectric layer 106 is, for example, an ABF-type film deposited by vacuum lamination. Level L1 of device 100 may further comprise other conductive or dielectric layers, not shown.

According to an embodiment, after step A, the layer 106 of the first dielectric material is locally removed (step B) to create at least one opening 108. This step B is, for example, carried out by laser direct imaging, which offers a fine precision of the area to be removed, or for example by an etching method by oxidizing treatment.

After step B, a protective mask 110 is applied (step C) in an additional level L2 of device 100 to leave the previously-formed at least one opening 108 accessible and protect the rest of the surface of the device so that only the openings are filled during a subsequent step. According to an embodiment, protective mask 110 is deposited as a solid film. This enables, for example, not to contaminate openings 108 with the material of protective mask 110.

After step C, a second dielectric material is deposited (step D) to fill the at least one opening 108 previously formed in the layer 106 of the first dielectric material and thus form a dielectric layer 112. Mask 110 is then removed. The deposition of dielectric layer 112 may be performed, for example, by liquid-phase deposition. The composition and the dielectric properties of the material of layer 112 are different from the composition and from the dielectric properties of the material of layer 106. For example, the dielectric permittivity of the first dielectric material is higher than the dielectric permittivity of the second dielectric material.

For example, each of dielectric layers 106, 112 is made of a dielectric material with a distinct dielectric constant, for example in the range from 2 to 10 and for example in the range from 3 to 5. The value of the dielectric constant varies according to the composition characteristic of the material.

Subsequent usual manufacturing steps may be carried out, for example, for the addition of additional levels to device 100.

The obtained device 100 (as shown in step D) contains at least two distinct dielectrics in contact and in a same level (for example, level L1) of the device.

FIG. 1B illustrates simplified cross-section views of successive steps A′ to G′ of a method of manufacturing a laminated electronic device according to a second embodiment. Certain steps of the method are identical to those of FIG. 1A and are not detailed again.

According to the embodiment of FIG. 1B, a device 100′ initially comprises substrate 104 and, at a step A′, the layer 106 of the first dielectric material is deposited to form level L1, as described above in relation with the device 100 of FIG. 1A.

After step A′, at least two openings 108, 109 are formed in the layer 106 of level L1 at step B′, according to methods identical to the step B of FIG. 1A.

After the creation of openings 108, 109 in layer 106, a mask 110′ is applied (step C′) to substrate 104, in an additional level L2, to mask over and cover at least one opening 109 and to leave at least one opening 108 uncovered.

After step C′, the at least one uncovered opening 108 is filled (step D′) with a layer 112′ of a second dielectric material at level L1 according to the method of step C of FIG. 1A. The composition and the dielectric properties of the second dielectric material are different from the composition and from the dielectric properties of the first dielectric material. For example, the dielectric permittivity of the second dielectric material is greater than the dielectric permittivity of the first dielectric material.

Once the second dielectric material has been deposited, the first mask 110′ is removed and a second mask 114′ is applied (step E′) to device 100′. This mask protects and covers layers 102 and 112′ and leaves at least one remaining opening 109 uncovered.

After step E′, a layer 116′ of a third dielectric material is deposited in the remaining openings 109 (step F′). The second mask 114′ is then removed. The composition and the dielectric properties of the third dielectric material are different from the composition and from the dielectric properties of the first and second dielectric materials. For example, the dielectric permittivity of the third dielectric material is higher than the dielectric permittivity of the second dielectric material, which is higher than the dielectric permittivity of the first dielectric material.

The obtained device 100′ (as shown in step G′) contains at least three distinct dielectric materials in the same level (for example, level L1) of the device, at least two of which are in contact in a same level of the device. For example, the layer 106 of the first dielectric material is in contact with the layer 112′ of the second dielectric material and the layer 106 of the first dielectric material is in contact with the layer 116′ of the third dielectric material.

The method of FIG. 1B describes the deposition of layers of two distinct dielectric materials in a layer of a third dielectric material. The method may be extended to the addition of at least three dielectric layers distinct from one another within a single level of a layer of a dielectric.

Substrate 104 or levels not shown above level L1 of the device 100 of FIG. 1A or 100′ of FIG. 1B may comprise conductive tracks. The conductive tracks can generate electromagnetic fields in level L1. The advantage of the structures obtained according to the methods of FIGS. 1A and 1B is that layers 112, 112′, and 116′ locally modify the electromagnetic field and can avoid or favor interference.

In addition to the forming of opening 108 in the dielectric layer at level L1 of FIG. 1A and/or of openings 108 and 109 in the dielectric layer 106 of level L1 of FIG. 1B, it will be possible to form one or a plurality of openings in these layers to form conductive vias. An advantage of the methods of FIGS. 1A and 1B is that similar techniques may be used for all openings, which facilitates the industrial implementation of the processes disclosed herein.

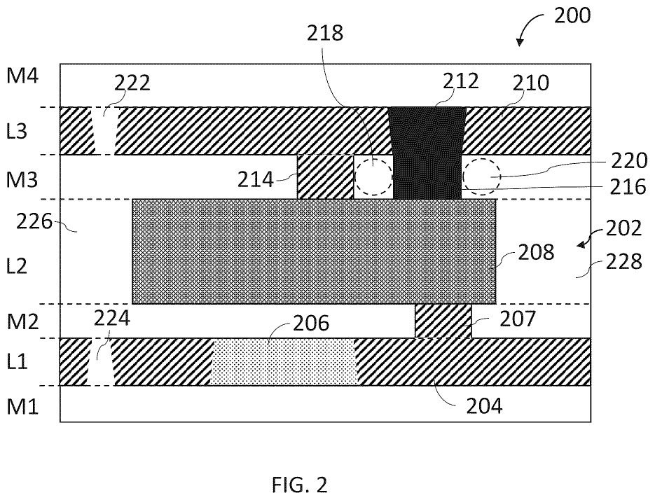

FIG. 2 schematically shows a cross-section view of an example of an electronic device 200 with a laminated structure.

Device 200 comprises four metallization levels M1, M2, M3, and M4 predominantly made of a conductive material 202, levels M1 and M2 being separated by a level L1 predominantly made of dielectric materials, levels M2 and M3 being separated by a level L2 predominantly made of dielectric materials, and levels M3 and M4 being separated by a level L3 predominantly made of dielectric materials. The dielectric layers electrically insulate the conductive tracks from one another and enable to delimit them. Level L1 comprises, for example, a layer 204 of a first dielectric material, and a layer 206 of a second dielectric material. Level L2 comprises, for example, a layer 208 of a third dielectric material, and layers of conductive material 202. Level L3 comprises, for example, a layer 210 of the first dielectric material, and a layer 212 of a fourth dielectric material. Metallization level M2 comprises, for example, a layer 207 of the first dielectric material crossing the layer of conductive material 202 of level M2 and extending between dielectric layers 204 and 208. Metallization level M3 comprises, for example, a dielectric layer 214, for example of the first dielectric material, crossing the layer of conductive material 202 of level M3 and extending between dielectric layers 208 and 210, and a dielectric layer 216, for example of the fourth dielectric material, crossing the layer of conductive material 202 of level M3 and extending between dielectric layers 208 and 212. Levels L1, L2, L3 predominantly made of dielectric materials are, for example, crossed by vias 222, 224, 226, 228, that is, by conductive layers coupling two metallization levels. For example, via 222 electrically couples levels M3 and M4, via 224 electrically couples levels M1 and M2, and vias 226 and 228 electrically couple levels M2 and M3.

Conductive material 202 is, for example, copper, gold, tin, silver, or an alloy of a plurality of these materials.

The first, second, third, and fourth dielectric materials are, for example, made of epoxy resin, ABF-type films, of silicon oxide, of alumina, of tantalum oxide, or of titanium oxide.

Levels L1 and L3 are, for example, obtained according to the manufacturing method of FIG. 1A or 1B.

Device 200 comprises, for example, layers of at least two distinct dielectric materials in contact in a same level and/or in two dielectric levels. For example, in the example of FIG. 2, dielectric layers 204, 207, and 208 are in contact, and dielectric layers 208, 216, and 212 are in contact.

The propagation of an electric current within a conductive track made of conductive material 202 generates an electromagnetic field in the surrounding layers of dielectric material. The properties of the electromagnetic field, for example the trajectory of the field lines or their amplitude are dependent on the properties of the crossed dielectric materials, for example on their dielectric permittivity.

The selection and the location of the layers of dielectric materials can thus be used to control the electromagnetic fields emitted in device 200. These fields contribute to the operation of a device, for example if the device is an antenna, or hinder its operation, for example by causing crosstalk.

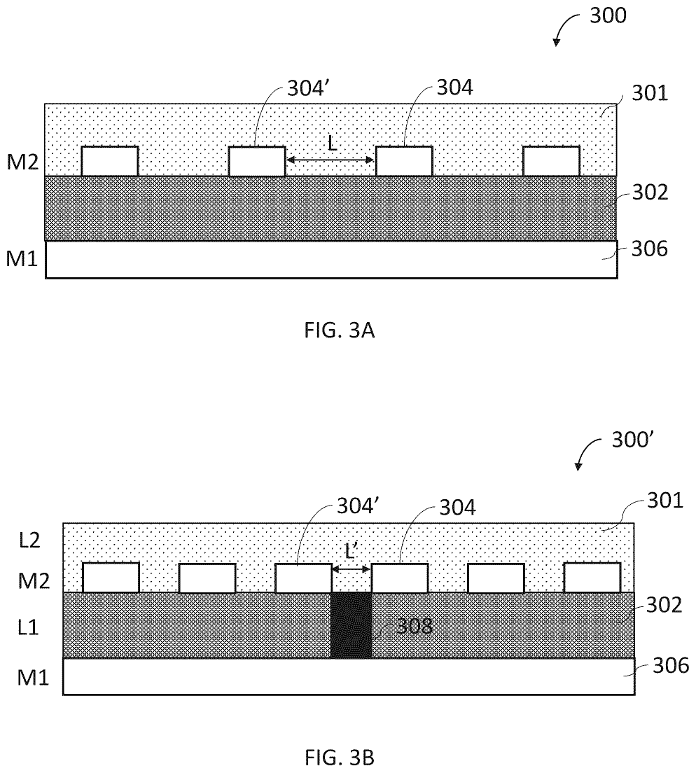

In the example of FIG. 2, level M4 corresponds, for example, to a ground plane of device 200. Electric currents flowing through the conductive tracks in areas 218 and 220 of level M3 create, for example, electromagnetic fields in the surrounding dielectric layers. In particular, field lines cross the layer 210 of the first dielectric material to couple the areas 218 and 220 of level M3 to ground plane M4. The electromagnetic fields originating from areas 218 and 220 may interfere with each other in the dielectric layers and cause a change in the electric signal transmitted by the tracks. To overcome these crosstalk effects, the two conductive tracks located in areas 218, 220 are separated by the layer 212 of the fourth dielectric material, having a dielectric permittivity that is, for example, lower than that of the neighboring layers 210 so that the amplitude of the electromagnetic fields is lower in layer 212 and thus so as to decrease the crosstalk likelihood. For example, in the presence of layers 210 with a dielectric permittivity of 4.3, a layer 212 with a dielectric 3.0 permittivity provides a 25% coupling energy decrease, a layer 212 with a 2.0 dielectric permittivity provides a 46% coupling energy decrease, and an air layer instead of layer 212 provides a 71% coupling energy decrease. This example is illustrated in further detail in FIGS. 3A and 3B.

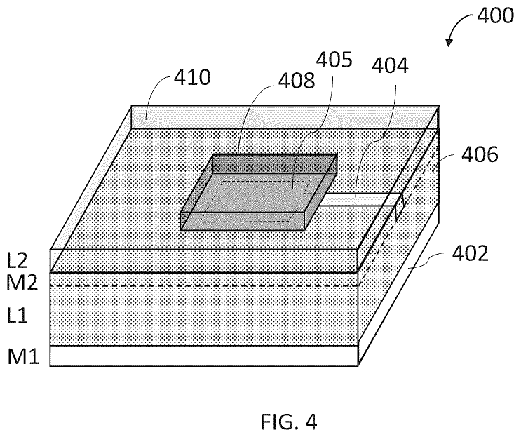

An electric current propagating in the metal tracks of level M2 creates an electromagnetic field in the layers 204, 206, and 208 of dielectric material of levels L1 and L2. The dielectric material of layer 206 has, for example, a higher dielectric permittivity than the materials of layers 204 and 208, to favor the emission of waves in this direction. For example, in the presence of layers 204, 208 with a 4.3 dielectric permittivity, a layer 206 with a 4.8 dielectric permittivity provides a 10% coupling energy increase, a layer 212 with a 5.2 dielectric permittivity provides a 15% coupling energy increase, and a layer 212 with a 6.0 dielectric permittivity provides a 30% coupling energy increase. This example is illustrated in further detail in FIG. 4.

FIG. 3A shows a cross-section view of an example of an electronic device 300 comprising two layers 301, 302 of dielectric materials and a plurality of conductive tracks 304, 304′, and 306.

In the example of FIG. 3A, the layer 302 of a dielectric material separates tracks 304 and 304′ from track 306. The layer 301 of a dielectric material, for example distinct from the dielectric material of layer 302, covers tracks 304, 304′. Tracks 304 and 304′ are in one metallization level M2 and are not in contact. Track 306 is in another metallization level M1 and is not in contact with tracks 304 and 304′.

Track 306 corresponds, for example, to a ground plane of the electronic circuit. Tracks 304 and 304′ are, for example, crossed by electric currents generating an electromagnetic field in the layer 302 of the dielectric material surrounding tracks 304 and 304′.

It is desired, for example, for the fields generated by two nearby tracks 304, 304′ not to interfere with each other. It is possible, for example, in order to avoid crosstalk, to separate tracks 304 and 304′ by a distance L greater than the minimum allowed by the technology standard, and by a distance, for example, approximately twice greater than this minimum, according to the level of current flowing through the tracks, for example by at least 70 micrometers. The electromagnetic field lines generated by tracks 304 and 304′ are then created between these tracks and ground 306, only slightly superimposing so as not to interfere.

However, increasing the distance between the electric tracks means increasing the size of the device, as well as the quantity of materials necessary for its manufacturing and its weight. An alternative solution provided by the present inventors consists, as illustrated in FIG. 3B, in integrating a layer of a dielectric material having dielectric properties configured to control the trajectory of the electromagnetic field lines and to avoid a potential crosstalk.

FIG. 3B shows a cross-section view of the example of the electronic device 300 of FIG. 3A, comprising a layer 308 of an additional dielectric material.

Certain elements of FIG. 3B are identical to elements of FIG. 3A and will not be detailed again.

An electronic device 300′ comprises two distinct dielectric materials 302 and 308 in a level L1 of the stack and conductive tracks 304, 304′, and 306 in metallization levels M1 and M2, on either side of level L1. Layer 301 is formed in a level L2, higher than level M2.

In addition to the elements of FIG. 3A, a layer 308 of a second dielectric material is formed at the level L1 located between levels M1 and M2. The composition and the dielectric properties of the dielectric material of layer 308 are different from the composition and from the dielectric properties of the dielectric material of layer 302. Layer 308 is, for example, formed according to the manufacturing method detailed in FIG. 1A. For example, layer 308 is formed between the upper surface of level M1, in contact with conductive track 306, and the lower surface of level M2. The width of layer 308 is, for example, equal to the distance L′ separating conductive tracks 304 and 304′ so that layer 308 is between tracks 304 and 304′ without overlapping therewith.

The described embodiments are, however, not limited to the specific example illustrated in FIG. 3B. For example, layer 308 could, for example, extend upwards in level M2, between the two tracks 304 and 304′.

Layer 308 has, for example, a lower dielectric permittivity than dielectric material 302. The dielectric permittivity being lower in layer 308, the lines of the electromagnetic field generated by an electric current flowing through tracks 304, 304′ will have their trajectory deviated to mainly remain in material 302.

Thus, the distance L′ separating tracks 304 and 304′ may be decreased as compared with the distance L of FIG. 3A. For example, L′ is equal to the minimum allowed by the reference manufacturing technologies, for example equal to approximately 40 micrometers.

FIG. 4 schematically shows a three-dimensional view of an example of a patch antenna 400.

According to an embodiment, it is desirable to favor electromagnetic fields generated in electronic device 400. In certain embodiments, electromagnetic fields are controlled to control their parameters, for example their amplitude, the field line trajectories, etc., which are, for example, configured to meet certain standards, for example, the Bluetooth, 5G, standard, etc. The addition of one or of multiple dielectric layers enables, for example, to obtain a better control of the field lines and in certain cases amplification of the obtained field by guiding it. An advantage of the addition of one or of multiple dielectric layers, with an appropriate selection of materials, is to enable to integrate a device by decreasing the integration impact, that is, to preserve the operating properties of the device during its integration, for example to preserve the gain associated with an antenna during the integration of the component.

An antenna 400 comprises, for example, a first conductive track 402 in a first metallization level M1, a second conductive track 404 in a second metallization level M2, and an antenna element 405, shown in dotted lines in FIG. 4, and capable of taking various forms according to the types of waves to be transmitted or received by patch antenna 400. Track 402 is, for example, separated from track 404 and from element 405 by a dielectric layer 406 in an intermediate level L1 between levels M1 and M2. Conductive track 402 is, for example, the circuit ground and conductive track 404 is, for example, crossed by an electric current to transmit or receive an electromagnetic field through antenna element 405.

The level M2 comprising track 404 and the element is, for example, covered by at least a first layer 408 and a second layer 410 of distinct dielectric materials in a level L2. The composition and the dielectric properties of the material of layer 408 are different from the composition and from the dielectric properties of the material of layers 410. In certain cases, the material of one of layers 408 and 410 is identical to material 406. Level L2 is, for example, obtained according to the method described in relation with FIG. 1A or 1B.

The layer 408 of level L2 at least partially, and preferably entirely, for example, covers antenna element 405. Layer 410 surrounds, for example, layer 408 at level L2.

The dielectric properties of the material of layer 408 are selected, for example, to locally guide or amplify the field. For example, the dielectric material of layer 408 may have a lower dielectric permittivity than the dielectric materials of the neighboring layers 406 and 410. Providing a dielectric permittivity of material 410 higher than that of layers 406 and 408 layers enables to insulate layer 408 from the direct environment to be less susceptible to the direct environment, and to integrate antenna 400. Providing a dielectric permittivity of material 408 lower than that of layers 406 and 410 enables to favor the emission of waves from layer 408 to the neighboring layers 406, 410 having higher dielectric permittivities. These choices of dielectric permittivities enable to locally guide and amplify the field.

The patch antenna 400 described in relation with FIG. 4 is, for example, integrated in an electronic device, such as a cell phone, a computer, or an electronic tablet.

An advantage of providing at least two layers of dielectric materials distinct from one another in a same level is a better control of the electromagnetic fields emitted in an electronic circuit in order to avoid unwanted interference and to control it when it does occur.

Another advantage is the compatibility between the manufacturing methods implemented by this solution and usual manufacturing methods for integrated electronic circuits.

Another advantage is a better integration with no performance loss.

Various embodiments and variants have been described. Those skilled in the art will understand that certain features of these various embodiments and variants may be combined, and other variants will occur to those skilled in the art. In particular, the number of levels and of layers present in the different drawings are only examples, which can be extended to other configurations. The examples of applications described in FIGS. 2 to 4 illustrate different applications of the described principles in a non-exhaustive manner.

1. A method of manufacturing a laminated structure, comprising one or a plurality of metal tracks, the method comprising:
depositing a first layer made of a first dielectric material on a substrate;
forming one or a plurality of openings in the first layer; and
depositing a second dielectric material at the location of the openings formed in the first layer;
wherein the second dielectric material has dielectric properties distinct from dielectric properties of the first dielectric material.

2. The method according to claim 1, wherein depositing the first layer comprises depositing by lamination.

3. The method according to claim 1, wherein forming one or the plurality of openings comprises performing direct laser imaging.

4. The method according to claim 1, further comprising depositing a mask on a surface of the first dielectric material after the forming of one or a plurality of openings, said mask including a mask opening at the one or the plurality of openings, wherein said mask protects the surface of the first dielectric material when depositing the second dielectric material.

5. The method according to claim 1, wherein the one or the plurality of openings comprises a first opening and a second opening, further comprising depositing a mask on a surface of the first dielectric material, said mask including a mask opening at the first opening, and wherein the mask covers the second opening and protects the surface of the first dielectric material when depositing the second dielectric material.

6. The method of claim 5, further comprising removing the mask and filling the second opening with a third dielectric material, wherein the third dielectric material has dielectric properties distinct from dielectric properties of the first and second dielectric materials.

7. The method of claim 6, further comprising depositing a further mask on the surface of the first dielectric material, said mask including a further mask opening at the second opening, and wherein the further mask covers the first opening and protects the surface of the first and second dielectric materials when depositing the third dielectric material.

8. The method according to claim 1, wherein the first layer made of the first dielectric material is a film of Ajinomoto buildup film (ABF) type.

9. The method according to claim 1, wherein the second dielectric material has a higher dielectric permittivity than the first dielectric material.

10. The method according to claim 1, wherein the second dielectric material has a lower dielectric permittivity than the first dielectric material.

11. The method according to claim 1, wherein a dielectric constant of the second dielectric material is in a range from 3 to 5.

12. The method according to claim 1, wherein the second dielectric material is deposited in liquid form.

13. An electronic device, with a laminated structure comprising:
one or a plurality of metal tracks;
a substrate;
a first layer made of a first dielectric material, wherein the first layer includes one or a plurality of openings; and
a second layer made of a second dielectric material, wherein the second layer is present in said one or the plurality of openings and in contact with the first layer, wherein the second dielectric material has dielectric properties distinct from the first dielectric material, and wherein the first layer and the second layer are present in a same level of the device.

14. The device according to claim 13, wherein the first layer made of the first dielectric material is a film of Ajinomoto buildup film (ABF) type.

15. The device according to claim 13, wherein the second dielectric material has a higher dielectric permittivity than the first dielectric material.

16. The device according to claim 13, wherein the second dielectric material has a lower dielectric permittivity than the first dielectric material.

17. The device according to claim 13, wherein a dielectric constant of the second dielectric material is in a range from 3 to 5.

18. The device according to claim 13, wherein the first layer and the second layer are present in a first level of the device, the device further comprising a second level comprising a third layer made of a third dielectric material, the third layer being in contact with at least one of the first layer or the second layer.

19. An antenna, comprising, in a laminated structure:
a first metal track in a first level;
a second metal track in a second level;
a first layer made of a first dielectric material;
a second layer made of a second dielectric material having dielectric properties distinct from the first dielectric material;
the second layer being present in openings in the first layer and being in contact with the first layer;
wherein the first layer and the second layer are present in a third level so that the second layer covers the second metal track;
wherein a dielectric constant of the second dielectric material is lower than a dielectric constant of the first dielectric material; and
a third layer made of a third dielectric material;
wherein a dielectric constant of the third dielectric material is higher than the dielectric constant of the second dielectric material; and
wherein the third layer is formed in a fourth level located between the first level and the second level.

20. A method of manufacturing a laminated structure of an antenna comprising a substrate and one or more metal tracks, the method comprising:
forming a first metal track in a first level;
depositing a first layer made of a first dielectric material in a second level;
forming a second metal track in a third level;
depositing a second layer made of a second dielectric material in a fourth level;
forming one or more openings in the second layer;
depositing a third layer made of a third dielectric material, having dielectric properties distinct from the second dielectric material, in the one or more openings;
wherein the second layer and fourth layer are formed in the fourth level so that the third layer covers the second metal track; and
wherein a dielectric constant of the third dielectric material is less than a dielectric constant of the second dielectric material.
